(19) United States
(12) Patent Application Publication
(10) Pub. No.: US 2008/0089018 A1
(43) Pub. Date: Apr. 17, 2008

(54) Gasket and Display Apparatus Having the Same

(76) Inventors: Jae-Kook KIM, Asan-si (KR); Ha-Yun Kang, Asna-si (KR)

Correspondence Address: MACPHERSON KWOK CHEN & HEID LLP, 2033 GATEWAY PLACE, SUITE 400, SAN JOSE, CA, 95110, US

(21) Appl. No.: 11/859,522

(22) Filed: Sep. 21, 2007

(30) Foreign Application Priority Data
Sep. 22, 2006 (KR) 2006-92469

(51) Int. Cl. G06F 1/16; H05K 9/00

(52) U.S. Cl. 361/681; 361/818

(57) ABSTRACT

In a gasket and a display apparatus having the gasket, the gasket is interposed between a circuit board and a protective member to transmit electromagnetic waves generated from the circuit board to the protective member. The elastic member separates the circuit board from the protective member. The conductive member surrounds the elastic member and electrically connects the circuit board with the protective member to transmit the electromagnetic waves. The supporting member is provided between the elastic member and the conductive member to support the contact area of the gasket making contact with the circuit board. The adhesive member is provided on the conductive member corresponding to the supporting member to bond the conductive member to the circuit board. Thus, the gasket is not separated from the circuit board, thereby preventing malfunction of the display apparatus.

### CROSS-REFERENCE TO RELATED APPLICATION

This application claims the benefit of priority to Korean Patent Application No. 2006-92469 filed on Sep. 22, 2006, the contents of which are herein incorporated by reference in its entirety.

### BACKGROUND OF THE INVENTION

1. Field of the Invention

The present invention relates to a gasket and a display apparatus having the same. More particularly, the present invention relates to a gasket and a display apparatus having the gasket, capable of preventing the display apparatus from experiencing a malfunction caused by electromagnetic waves.

2. Description of the Related Art

In general, a liquid crystal display includes a liquid crystal display panel for displaying an image, a printed circuit board for controlling the liquid crystal display panel, a bottom chassis on which the liquid crystal display panel is settled, and a top chassis coupling the liquid crystal display panel with the bottom chassis. The bottom chassis and the top chassis include a plurality of sidewalls, respectively, and are coupled with each other such that the sidewalls face each other. When the printed circuit board is placed between the sidewalls of the bottom chassis and the top chassis, electromagnetic waves generated from the printed circuit board are emitted to the top chassis through a gasket which is provided between the printed circuit board and the top chassis.

Since the gasket on the printed circuit board has a certain height, when the top chassis is coupled with the bottom chassis, the gasket is pushed by the sidewalls of the top chassis so that the gasket is separated from the printed circuit board or the gasket is deformed.

In addition, if the top chassis and the bottom chassis are not stably coupled with each other, a gap is formed between the sidewalls and the top chassis is easily moved. If the top chassis is moved, the gasket is pushed or deformed by means of the top chassis. Thus, the gasket does not stably make contact with the printed circuit board and the top chassis, so the electromagnetic waves are rarely emitted through the gasket.

As a result, the height of the gasket is limited below a certain height, so that a sufficient contact area is not ensured between the gasket and the printed circuit board.

### SUMMARY OF THE INVENTION

A gasket allowing electromagnetic waves to be stably emitted from a circuit board to a protective member is described.

A display apparatus having the gasket is also provided.

In an exemplary embodiment of the present invention, a gasket includes an elastic member, a conductive member, a supporting member and an adhesive member.

The elastic member is interposed between the circuit board and the protective member to separate the circuit board from the protective member. The elastic member includes an elastic polymer having a predetermined thickness. The conductive member surrounds the elastic member and electrically connects the circuit board with the protective member to transmit electromagnetic waves. The conductive member includes a conductive fiber.

The supporting member is provided between the elastic member and the conductive member in an area making contact with the circuit board to support the contact area. The supporting member includes materials such as plastic materials or metallic materials. The adhesive member is provided on the conductive member corresponding to the supporting member to bond the conductive member to the circuit board. The adhesive member includes a conductive adhesive tape.

In another exemplary embodiment of the present invention, a display apparatus includes a receiving member, a display panel, a printed circuit board, a top chassis and a gasket.

The display panel is settled on the receiving member to display an image in response to a driving signal. The printed circuit board is electrically connected with the display panel to provide the driving signal to the display panel, and is provided adjacent to one side of the receiving member. The top chassis is coupled with the receiving member while facing the receiving member to cover an edge part of the display panel and the printed circuit board. The gasket includes an elastic member, a conductive member, a supporting member and an adhesive member.

The elastic member separates the printed circuit board from the top chassis. The conductive member surrounds the elastic member, and electrically connects the printed circuit board with the top chassis. The supporting member is provided between the elastic member and the conductive member in an area making contact with the printed circuit board to support the contact area. The adhesive member is provided on the elastic member in an area, in which the supporting member is formed, to bond the gasket to the printed circuit board.

The elastic member includes an elastic polymer having a predetermined thickness. The conductive area is formed on the printed circuit board making contact with the gasket, and the conductive area includes metallic materials. The top chassis includes metallic materials, and the conductive member includes a conductive fiber, and the adhesive member includes a conductive adhesive tape. The electromagnetic waves generated from the printed circuit board are transmitted to the top chassis through the conductive area, the adhesive member and the conductive member.

In another exemplary embodiment of the present invention, a display apparatus is provided, comprising: a receiving member; a display panel provided on the receiving member for displaying an image in response to a driving signal; a printed circuit board electrically connected with the display panel to provide the driving signal to the display panel, the printed circuit board being provided adjacent to one side of the receiving member; a top chassis coupled with the receiving member and covering an edge portion of the display panel and the printed circuit board; and a conductive gasket interposed between the printed circuit board and the top chassis. The gasket comprises: a conductive outer layer electrically connecting the printed circuit board and the top chassis; an adhesive member adhering a portion of the conductive outer layer to the printed circuit board; an elastic member contained within the conductive outer layer; and a supporting member provided between elastic member and the portion of the conductive outer layer adhered to the printed circuit board.

According to the above, the gasket is not separated from the circuit board or deformed by external impact or movement of a protective member. Thus, the contact area between the circuit board and the gasket may be uniformly maintained, and as a result, the electromagnetic waves generated from the circuit board may be emitted to the protective member through the gasket.

### BRIEF DESCRIPTION OF THE DRAWINGS

The above and other advantages of the present invention will become readily apparent by reference to the following detailed description when considered in conjunction with the accompanying drawings wherein:

FIG. 1A is an exploded perspective view showing an exemplary embodiment of a liquid crystal display according to the present invention;

FIG. 1B is a sectional view taken along a line I-I′ shown in FIG. 1A;

FIG. 2A is a plan view showing a liquid crystal display panel and a printed circuit board shown in FIG. 1A;

FIG. 2B is a sectional view taken along a line III-III′ shown in FIG. 2A;

FIG. 3 is a partially-cut enlarged sectional view of a portion II shown in FIG. 1B;

FIG. 4A is a perspective view showing a gasket shown in FIG. 1A;

FIG. 4B is a sectional view taken along a line IV-IV′ shown in FIG. 4A; and

FIG. 5 is a sectional view explaining an effect of a gasket shown in FIG. 4A.

### DESCRIPTION OF THE EMBODIMENTS

Hereinafter, embodiments the present invention will be explained in detail with reference to the accompanying drawings. However, the scope of the present invention is not limited to such embodiments and the present invention may be realized in various forms. The embodiments to be described below are provided to fully describe the present invention and to assist those skilled in the art to completely understand the present invention. The present invention is defined only by the scope of the appended claims. In addition, the size of regions shown in the drawings can be simplified or magnified for the purpose of clear explanation. Also, the same reference numerals are used to designate the same elements throughout the drawings.

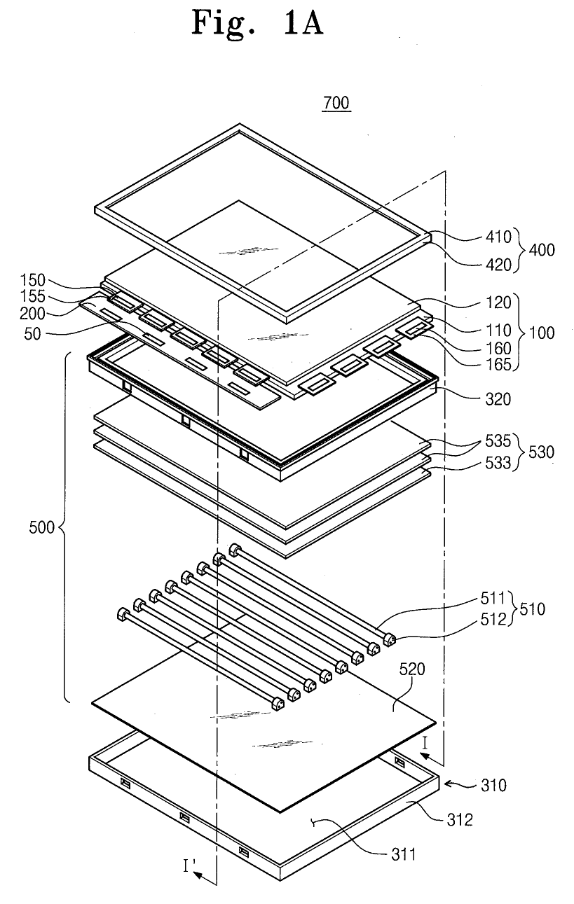

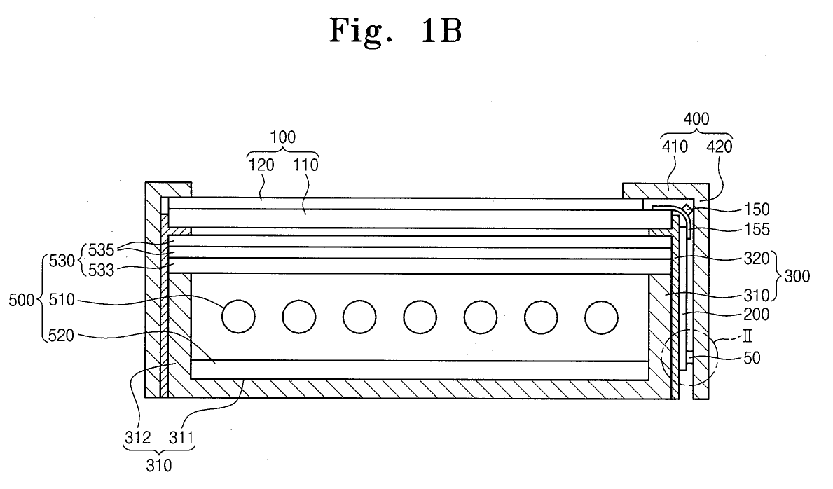

FIG. 1A is an exploded perspective view showing an exemplary embodiment of a liquid crystal display according to the present invention, and FIG. 1B is a sectional view taken along a line I-I′ shown in FIG. 1A.

Referring to FIGS. 1A and FIG. 1B, a liquid crystal display 700 according to an exemplary embodiment of the present invention includes a liquid crystal display panel 100, a printed circuit board 200, a receiving member 300, a top chassis 400 and a gasket 50. Although FIGS. 1A and 1B show the liquid crystal display 700 as an example of the display apparatus, this is for illustrative purposes only, and the present invention is not limited thereto. Therefore, other display apparatuses may be used for the present invention.

The liquid crystal display (“LCD”) panel 100 is positioned on the receiving member 300. The LCD panel 100 displays an image in response to a driving signal from the printed circuit board 200 provided in one side of the receiving member 300. The top chassis 400 is coupled with the receiving member 300 while facing the receiving member 300, and covers an edge portion of the liquid crystal display panel 100 and the printed circuit board 200. The gasket 50, which is interposed between the printed circuit board 200 and the top chassis 400, transmits electromagnetic waves generated from the printed circuit board 200 to the top chassis 400.

In addition, the liquid crystal display 700 further includes a backlight unit 500 received in a lower part of the LCD panel 100 to uniformly provide light to the liquid crystal display panel 100. In the present exemplary embodiment, the backlight unit 500 is a direct illumination type backlight unit.

The backlight unit 500 includes a light source 510, a reflection plate 520 and an optical sheet 530. The reflection plate 520, the light source 510 and the optical sheet 530 are sequentially received in the receiving member 300.

The light source 510 includes a fluorescent lamp 511 and a lamp holder 512. Plural light sources 510 are provided in the receiving member 300 and arranged along a direction substantially perpendicular to a longitudinal direction of the fluorescent lamp 511. The lamp holder 512 is coupled to each end of the fluorescent lamp 511 to fix the fluorescent lamp 511 to the receiving member 300. Electrode lines (not shown), which receive the power from the exterior, are provided at each end of the fluorescent lamp 511, and the electrode lines extend to the exterior through holes formed in the lamp holder 512.

The reflection plate 520 is received at the lower part of the light source 510 in the receiving member 300, and reflects the light from the light source 510 toward the optical sheet 530. The optical sheet 530 is received between the liquid crystal display panel 100 and the light source 510 in the receiving member 300, and controls the optical characteristics of the light provided from the light source 510 to provide the light to the liquid crystal display panel 100. The optical sheet 530 includes a diffusion sheet 533 for diffusing the light and a prism sheet 535 for collecting the light, and thus serves to improve the brightness and viewing angle of the light exiting therefrom.

The receiving member 300 includes a bottom chassis 310 and a mold frame 320. In the present exemplary embodiment, the bottom chassis 310 includes a first bottom surface 311 and a first sidewall 312 extending from an end of the first bottom surface 311 to provide a receiving space. The reflection plate 520 and the light source 510 are sequentially received in the receiving space. The optical sheet 530 is settled and supported on an upper part of the first sidewall 312 of the bottom chassis 310. In addition, the bottom chassis 310 is provided at a rear side thereof with an inverter (not shown) which supplies the power to the fluorescent lamp 511.

The mold frame 320 has a frame shape, and is provided to surround the first sidewall 312 of the bottom chassis 310. The mold frame 320 is provided with a bar protruding from the sides of the mold frame 320 toward the upper part of the optical sheet 530. The liquid crystal display panel 100 is settled on the bar of the mold frame 320. The liquid crystal display panel 100 is spaced apart from the optical sheet 530 by a predetermined distance by means of the mold frame 320, and the liquid crystal display panel 100 is settled on the receiving member 300 by the mold frame 320.

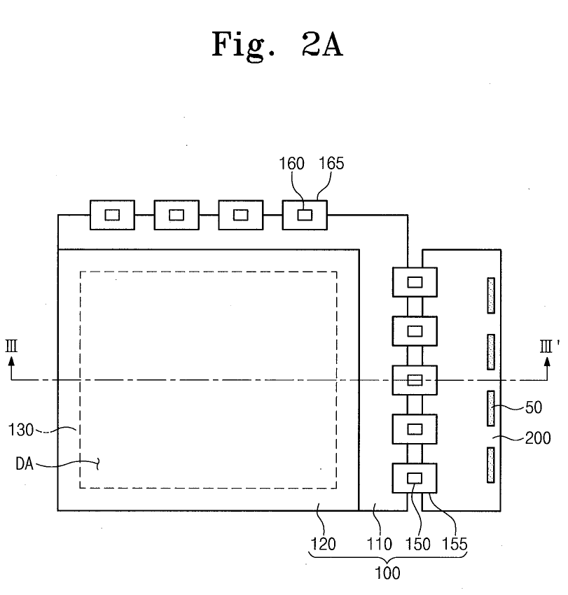

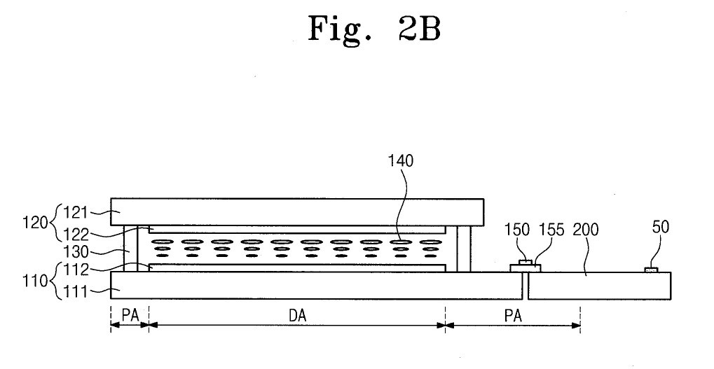

Hereinafter, the liquid crystal display panel 100 and the printed circuit board 200 will be described with reference to FIGS. 2A and 2B.

FIG. 2A is a plan view showing a liquid crystal display panel and a printed circuit board shown in FIG. 1A, and FIG. 2B is a sectional view taken along a line III-III′ shown in FIG. 2A.

Referring to FIGS. 2A and 2B, the liquid crystal display panel 100 includes an array substrate 110, a color filter substrate 120, a liquid crystal layer 140 interposed between the array substrate 110 and the color filter substrate 120, a sealant 130, a data driving chip 150 and a gate driving chip 160.

The liquid crystal display panel 100 includes a display area DA on which the image is displayed and a peripheral area PA surrounding the display area DA. The array substrate 110 includes a first base substrate 111 and a pixel array layer 112, which has a plurality of pixels arranged in the form of a matrix, formed on the first base substrate 111. The pixel array layer 112 is provided in the display area DA. Although not shown in FIGS. 2A and 2B, each of the pixels is defined by gate lines and data lines, which cross each other while being insulated from each other, and includes a thin film transistor and a pixel electrode electrically connected to the thin film transistor.

The thin film transistor switches a pixel voltage applied to the pixel electrode. The data line applies the pixel voltage to the corresponding thin film transistor, and the gate line applies a gate voltage to the corresponding thin film transistor. Thus, each pixel applies the pixel voltage to the pixel electrode in response to the gate voltage.

The color filter substrate 120 is coupled with the array substrate 110 while facing the array substrate 110. The color filter substrate 120 includes a second base substrate 121 and a color array layer 122 formed on the second base substrate 121. The color array layer 122 is provided in the display area DA, and includes a color filter layer, a black matrix and a common electrode. The color filter layer includes a plurality of color pixels corresponding to the plurality of pixels, and the black matrix is formed in the place corresponding to the gate line and the data line. The common electrode is provided on the color pixels and black matrix, while facing the pixel electrode. The common electrode receives a common voltage as a reference voltage. Therefore, a light transmittance of the liquid crystal layer 140 is controlled according to a potential difference between the pixel voltage and the common voltage, thereby displaying the image on the display area DA of the liquid crystal display panel 100.

In order to form the liquid crystal layer 140, liquid crystals are provided between the array substrate 110 and the color filter substrate 120 through a dropping method or a vacuum injection method. The alignment direction of the liquid crystal provided in the liquid crystal layer 140 is changed according to the voltage difference between the pixel voltage and the common voltage, and the transmittance of light from the backlight unit 500 is changed according to the alignment direction of the liquid crystal.

The sealant 130 provided in the peripheral area PA of the liquid crystal display panel 100 is interposed between the array substrate 110 and the color filter substrate 120, thereby coupling the array substrate 110 with the color filter substrate 120. Moreover, the sealant 130 seals the liquid crystal layer 140 such that the liquid crystal layer 140 may be prevented from being leaked.

The data driving chip 150 and the gate driving chip 160 are provided at sides of the liquid crystal display panel 100, respectively. The data driving chip 150 is electrically connected with the data lines, and outputs the pixel voltage to the data line. The gate driving chip 160 is electrically connected with the gate lines, and sequentially outputs the gate voltage to the gate lines.

The liquid crystal display 700 further includes a first tape carrier package (hereinafter, referred to as ‘TCP’) 155 on which the data driving chip 150 is mounted, and a second TCP 165 on which the gate driving chip 160 is mounted. The first TCP 155 electrically connects the printed circuit board 200 with the liquid crystal display panel 100.

The printed circuit board 200 generates a driving signal which controls an operation of the data driving chip 150 and the gate driving chip 160. The printed circuit board 200 outputs an image data signal, a data control signal and a gate driving signal to the liquid crystal display panel 100 through the first TCP 155. The data driving chip 150 mounted on the first TCP 155 receives the data control signal and the image data signal from the printed circuit board 200 through the first TCP 155 to convert the image data signal into the pixel voltage. Then, the data driving chip 150 applies the pixel voltage to the data line of the liquid crystal display panel 100 through the first TCP 155.

The gate driving chip 160 mounted on the second TCP 165 receives the gate driving signal from the printed circuit board 200 through the first TCP 155 and a signal transmission line (not shown) that is arranged on the liquid crystal display panel 100 to output the gate voltage. The gate driving chip 160 applies the output gate voltage to the gate line of the liquid crystal display panel 100 through the second TCP 165.

Meanwhile, the gasket 50 is provided on an upper surface of the printed circuit board 200 to absorb the electromagnetic waves generated from the printed circuit board 200 and emit the electromagnetic waves to the top chassis 400.

Referring again to FIGS. 1A and 1B, the liquid crystal display panel 100 is settled on the mold frame 320, and is provided at an upper part of the backlight unit 500. The liquid crystal display panel 100 receives the light provided from the light source 510, and displays the image in response to the driving signal provided from the printed circuit board 200. The first TCP 155 is bent such that the printed circuit board 200 is settled on one side of the receiving member 300. Accordingly, the printed circuit board 200 is provided adjacent to the one side of the receiving member 300.

The top chassis 400 includes an upper surface 410 and a second sidewall 420 extending from the upper surface 410 to have a clamp-like shape. The top chassis 400 is coupled with the bottom chassis 310 such that the second sidewall 420 faces the first sidewall 312, thereby fixing the liquid crystal display panel 100 to the mold frame 320. The upper surface 410 of the top chassis 400 covers the edge part of the liquid crystal display panel 100, that is, the peripheral area PA, and the second sidewall 420 of the top chassis 400 covers the printed circuit board 200.

The gasket 50, which is provided at one side of the printed circuit board 200, makes contact with the second sidewall 420 of the top chassis 400. When the top chassis 400 is coupled with the bottom chassis 310 while facing the bottom chassis 310, the gasket 50 is pressed back to the bottom chassis 310 by means of the top chassis 400, so that the gasket 50 may be electrically connected with the top chassis 400.

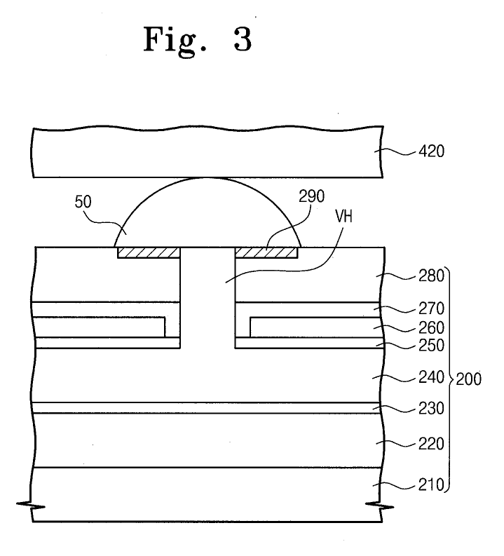

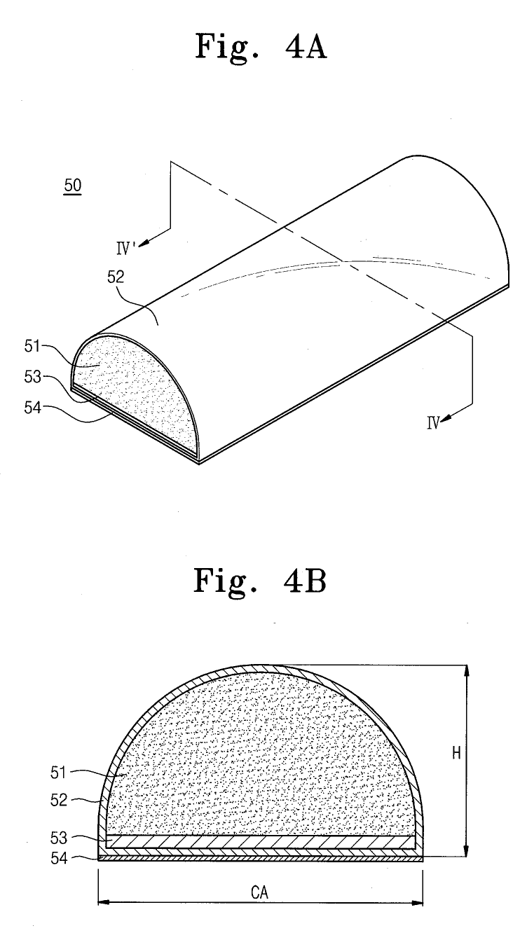

FIG. 3 is a partially-cut enlarged sectional view of a portion II shown in FIG. 1B. FIG. 4A is a perspective view showing a gasket shown in FIG. 1A, and FIG. 4B is a sectional view taken along a line IV-IV′ shown in FIG. 4A.

Referring to FIG. 3, the gasket 50 is interposed between the printed circuit board 200 and the second sidewall 420 of the top chassis 400 in order to transmit the electromagnetic waves generated from the printed circuit board 200 to the top chassis 400.

The printed circuit board 200 has a multi-layered structure including a first interconnection 220, a ground 240, a power source 260 and a second interconnection 280. The first interconnection 220 is formed on a base layer 210, which is located below the first interconnection 220, and the base layer 210 includes epoxy resin. The first interconnection 220 and the second interconnection 280 include a plurality of interconnection patterns. The ground 240 includes a single metal plate, and the power source 260 includes a plurality of metal plates spaced apart from each other.

The printed circuit board 200 further includes a first insulating layer 230, a second insulating layer 250 and a third insulating layer 270. The first insulating layer 230 is interposed between the first interconnection 220 and the ground 240 such that the first interconnection 220 may be insulated from the ground 240. The second insulating layer 250 is interposed between the ground 240 and the power source 260 such that the ground 240 may be insulated from the power source 260. The third insulating layer 270 is formed on the power source 260 to cover the metal plates, and the metal plates are insulated from each other. In addition, the power source 260 and the second interconnection 280 are insulated from each other.

In order to emit the electromagnetic waves generated from the printed circuit board 200 to the exterior, the gasket 50 is electrically connected to the ground 240. Thus, the printed circuit board 200 is provided with a via hole VH formed through the second interconnection 280, the third insulating layer 270 and the second insulating layer 250, such that the ground 240 and the gasket 50 are electrically connected to each other. The gasket 50 is provided on the second interconnection 280 in which the via hole VH is formed, and couples with the printed circuit board 200. The electromagnetic waves from the printed circuit board 200, which are introduced into the ground 240 through the via hole VH, are transmitted to the gasket 50.

The printed circuit board 200 includes a conductive area 290 on the second interconnection 280 in order to ensure a ground area between the gasket 50 and the printed circuit board 200. The conductive area 290 has a size corresponding to an area which makes contact with the gasket 50. The conductive area 290 includes metals such as copper, gold, etc., and electrically connects the printed circuit board 200 with the gasket 50.

Referring to FIGS. 4A and 4B, the gasket 50 includes an elastic member 51, a conductive member 52, a supporting member 53 and an adhesive member 54.

The elastic member 51 is interposed between the printed circuit board 200 and the top chassis 400 such that the printed circuit board 200 is spaced apart from the top chassis 400. The elastic member 51 includes an elastic polymer such as elastic rubber or polyurethane sponge. The elastic polymer is polymer having an elastic property, that is, the elastic polymer is stretched when pulled by an external force and returns to its original length when the external force is removed. Thus, when the top chassis 400 is coupled with the bottom chassis 310 while facing the bottom chassis 310, the elastic member 51 is easily pressed in a horizontal direction due to the elastic property, thereby increasing the contact area of the gasket 50 which makes contact with the printed circuit board 200 and the top chassis 400. Accordingly, the gasket 50 may stably make contact with the printed circuit board 200 and the top chassis 400.

The elastic member 51 has a predetermined thickness such that the second sidewall 420 of the top chassis 400 is spaced apart from the printed circuit board 200 by a predetermined distance, and the gasket 50 may stably make contact with the printed circuit board 200 and the top chassis 400.

The conductive member 52 surrounds the elastic member 51, and electrically connects the printed circuit board 200 with the top chassis 400 to transmit the electromagnetic waves to the top chassis 400. The conductive member 52 includes a conductive fiber and a hot melt film. For instance, the conductive fiber is formed by plating polyester with metals such as copper or nickel. The hot melt film is an adhesive film, so when surrounding the elastic member 51 with the conductive fiber, the conductive fiber is bonded to the elastic member 51 after attaching the hot melt film to one side of the conductive fiber. The conductive member 52 includes the conductive fiber such that the electromagnetic waves generated from the printed circuit board 200 may be introduced into the top chassis 400 through the conductive fiber. Preferably, the conductive fiber has a surface resistance of 0.03 Ω/sq.

The supporting member 53 is provided between the elastic member 51 and the conductive member 52 in a contact area CA where the gasket 50 is coupled with the printed circuit board 200, and the supporting member 53 supports the contact area CA. In particular, the supporting member 53 has a size corresponding to the contact area CA, and includes rigid materials. For example, the supporting member 53 may include insulating plastic materials such as polyethylene terephthalate. In addition, the supporting member 53 may include conductive metallic materials.

The supporting member 53 presses the gasket 50 against the printed circuit board 200 in the contact area CA such that the portions of the gasket 50 corresponding to the contact area CA are not separated from the printed circuit board 200 by external forces. Accordingly, since a frictional force between the gasket 50 and the printed circuit board 200 in the contact area CA is high, the gasket 50 may maintain the contact state with the printed circuit board 200. In addition, the supporting member 53 has an uniform surface flatness, so the gasket 50 does not lift up and separate from the contact area CA.

The supporting member 53 may be fixed between the elastic member 51 and the conductive member 52 by using an adhesive, so that the supporting member 53 is not separated from a region between the elastic member 51 and the conductive member 52.

In this manner, since the gasket 50 is stably coupled with the printed circuit board 200 by the supporting member 53, the gasket 50 may be prevented from being separated from the printed circuit board 200 by the external impact. More specifically, when the top chassis 400, which is provided in an upper part of the gasket 50, is moved, the contact area CA of the gasket 50 may be prevented from being lifted up by the second sidewall 420 of the top chassis 400. Moreover, since the supporting member 53 includes a rigid material and has a uniform surface flatness, the contact area CA can be uniformly maintained.

The adhesive member 54 is provided on the conductive member 52 while corresponding to the supporting member 53, and bonds the gasket 50 to the printed circuit board 200. The adhesive member 54 includes a conductive adhesive tape. The conductive adhesive tape may be a double-sided tape having an adhesive property. One side of the conductive adhesive tape is adhered to the contact area CA of the gasket 50, and the other side of the conductive adhesive tape is adhered to the conductive area 290 on the printed circuit board 200 to couple the gasket 50 with the printed circuit board 200.

As an example of the present exemplary embodiment, the conductive adhesive tape is formed by plating mesh-type fiber with nickel powder, and by coating the adhesive onto the upper part thereof. The adhesive member 54 has a constant adhesive intensity such that the gasket 50 is not separated from the printed circuit board 200. In the present exemplary embodiment, the adhesive member 54 has the adhesive intensity of at least 800 gf/25 mm.

The electromagnetic waves generated from the printed circuit board 200 are transmitted to the top chassis 400 through the conductive area 290, the adhesive member 54 and the conductive member 52.

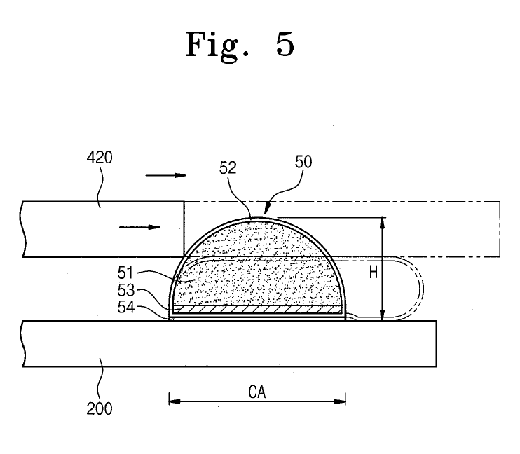

FIG. 5 is a sectional view explaining an effect of the gasket shown in FIG. 4A according to the present invention.

Referring to FIG. 5, the gasket 50 according to an exemplary embodiment of the present invention is not separated from the printed circuit board 200 and is not deformed, so the gasket 50 allows the electromagnetic waves generated from the printed circuit board 200 to be emitted to the top chassis 400.

More specifically, when the top chassis 400 is coupled with the bottom chassis 310, the second sidewall 420 slides on the upper part of the gasket 50 which is coupled with the printed circuit board 200. Because the gasket 50 has a certain thickness H, the upper part of the gasket 50 is pushed by the second sidewall 420. However, since the supporting member 53 supports the contact area CA of the gasket 50 which makes contact with the printed circuit board 200, the gasket 50 does not lift up and separate from the printed circuit board 200.

In addition, due to the elastic property of the elastic member 51, as the gasket 50 is pressed in the horizontal direction, the gasket 50 is deformed and a portion of the surface of the gasket 50 which had previously not contacted the printed circuit board 200 is then put in contact with the printed circuit board 200. Accordingly, the total surface area of the gasket 50 which makes contact with the printed circuit board 200 is increased. Thus, the gasket 50 may provide a contact area larger than the contact area CA, and the gasket 50 may stably make contact with the printed circuit board 200 and the top chassis 400. Accordingly, the printed circuit board 200 is stably grounded with the top chassis 400 through the gasket 50, and as a result, the electromagnetic waves generated from the printed circuit board 200 are emitted to the top chassis 400 through the gasket 50.

As described above, according to the gasket and the display apparatus having the gasket, the supporting member supports the contact area of the gasket which makes contact with the circuit board such that the gasket is not separated from the circuit board or deformed by the movement of the protective member. Accordingly, the gasket stably grounds the circuit board with the protective member, and transmits the electromagnetic waves generated from the circuit board to the protective member. Therefore, the circuit board may be prevented from being damaged by the electromagnetic waves, thereby preventing failure of the display apparatus.

Although the exemplary embodiments of the present invention have been described, it is understood that the present invention should not be limited to these exemplary embodiments but various changes and modifications can be made by one of ordinary skilled in the art within the spirit and scope of the present invention as hereinafter claimed.

What is claimed is:

1. A gasket for display apparatus comprising:
an elastic member;
a conductive member surrounding the elastic member, and transmitting electromagnetic waves;
a supporting member provided between a portion of the elastic member and the conductive member; and
an adhesive member provided on the conductive member opposite the supporting member.

2. The gasket of claim 1, wherein the elastic member comprises an elastic polymer having a predetermined thickness.

3. The gasket of claim 1, wherein the conductive member comprises a conductive fiber.

4. The gasket of claim 1, wherein the adhesive member comprises a conductive adhesive tape.

5. The gasket of claim 1, wherein the supporting member comprises a plastic material.

6. The gasket of claim 1, wherein the supporting member comprises metallic materials.

7. The gasket of claim 1, wherein a face of the gasket corresponding to the supporting member has a substantially flat shape.

8. A display apparatus comprising:
a receiving member;
a display panel provided on the receiving member for displaying an image in response to a driving signal;
a printed circuit board electrically connected with the display panel to provide the driving signal to the display panel, the printed circuit board being provided adjacent to one side of the receiving member;
a top chassis coupled with the receiving member and covering an edge portion of the display panel and the printed circuit board; and
a gasket interposed between the printed circuit board and the top chassis to transmit electromagnetic waves generated from the printed circuit board to the top chassis,
wherein the gasket comprises:
an elastic member interposed between the printed circuit board and the top chassis to separate the printed circuit board from the top chassis;
a conductive member surrounding the elastic member and electrically connecting the printed circuit board with the top chassis to transmit the electromagnetic waves;
a supporting member provided between a portion of the elastic member and the conductive member in an area making contact with the printed circuit board; and
an adhesive member provided on the conductive member opposite the supporting member to bond the gasket to the printed circuit board.

9. The display apparatus of claim 8, wherein the elastic member comprises an elastic polymer having a predetermined thickness.

10. The display apparatus of claim 9, wherein a conductive area is formed on the printed circuit board making contact with the gasket, and the conductive area comprises metallic materials.

11. The display apparatus of claim 10, wherein the top chassis comprises metallic materials, the conductive member comprises a conductive fiber, and the adhesive member comprises a conductive adhesive tape.

12. The display apparatus of claim 11, wherein the electromagnetic waves generated from the printed circuit board are transmitted to the top chassis through the conductive area, the adhesive member and the conductive member.

13. The display apparatus of claim 8, wherein a face of the gasket corresponding to the supporting member continuously makes contact with the circuit board.

14. The display apparatus of claim 8, wherein the supporting member is adhered to a face of the conductive member.

15. The display apparatus of claim 8, wherein the supporting member is adhered to a face of the elastic member.

16. A display apparatus comprising:
a receiving member;
a display panel provided on the receiving member for displaying an image in response to a driving signal;
a printed circuit board electrically connected with the display panel to provide the driving signal to the display panel, the printed circuit board being provided adjacent to one side of the receiving member;
a top chassis coupled with the receiving member and covering an edge portion of the display panel and the printed circuit board; and
a conductive gasket interposed between the printed circuit board and the top chassis,
said gasket comprising:
a conductive outer layer electrically connecting the printed circuit board and the top chassis;
an adhesive member adhering a portion of the conductive outer layer to the printed circuit board;
an elastic member contained within the conductive outer layer; and
a supporting member provided between elastic member and the portion of the conductive outer layer adhered to the printed circuit board.

17. The display apparatus of claim 16, wherein the supporting member is rigid and flat.

18. The display apparatus of claim 16, wherein electromagnetic waves generated from the printed circuit board are transmitted to the top chassis through the conductive area, the adhesive member, and the conductive member.
